(19) United States
(12) Patent Application Publication
(10) Pub. No.: US 2007/0206363 A1
(43) Pub. Date: Sep. 6, 2007

(54) Voltage regulator with welded lead frame connectors and method of making

(75) Inventors: Mario Cespedes, Winter Springs, FL (US); Terry Haskin, Orlando, FL (US); Ray Smith, Orlando, FL (US); An Huu Nguyen, Orlando, FL (US); John Lasek, South Daytona, FL (US)

Correspondence Address: RICHARD K. WARTHER;ALLEN, DYER,DOPPELT,MILBRATH & GILCHRIST P.A., 1401 CITRUS CENTER 255 SOUTH ORANGE AVENUE, P.O. BOX 3791, ORLANDO, FL, 32802-3791, US

(73) Assignee: WETHERILL ASSOCIATES, INC., Corporation of the State of Delaware, Royersford, PA (US)

(21) Appl. No.: 11/365,536

(22) Filed: Mar. 1, 2006

(51) Int. Cl. H01L 23/34

(52) U.S. Cl. 361/748; 257/712

(57) ABSTRACT

A voltage regulator controls voltage supplied from a generator or alternator and includes a voltage regulator body having at least one component receiving cavity. A lead frame is embedded within the voltage regulator body and forms external lead frame connectors and internal lead frame connectors. A voltage regulator integrated circuit and passive components are mounted within the at least one component receiving body and connected to the selected internal lead frame connectors. The lead frame can be configured such that one or more passive components are positioned over or under at least a portion of the voltage regulator IC.

### FIELD OF THE INVENTION

The present invention relates to the field of voltage regulators, and more particularly, the present invention relates to voltage regulators for controlling voltage and current supplied from a generator or alternator used in maritime, automobile, motorcycle or small engine charging systems.

### BACKGROUND OF THE INVENTION

The charging system for an automobile, truck, boat, motorcycle or small engine typically includes an alternator or generator with appropriate windings, armature and stator components. A voltage regulator regulates the charging voltage and output current to provide consistent alternator or generator operation during varying loads that would create voltage drops and other operational problems. Many different regulator designs are commercially available, including discrete transistor, custom integrated circuit systems using application specific integrated circuits (ASIC), or hard-wired circuits that define a specific function for a specific type of application. These voltage regulators typically require the use of a heat sink for drawing heat away from the active and passive voltage regulator components, which in many prior art devices, are mounted on a conventional printed circuit board (PCB) or printed wiring board (PWB) and sometimes included on a heat sink or ceramic material. The heat sink radiates excessive heat generated because of the voltage regulator operation into the atmosphere or mounting system.

Typically, many of the voltage regulator designs include a voltage regulator body having a component receiving cavity and a lead frame embedded within the voltage regulator body. This lead frame forms external lead frame connectors and may include some type of terminal connections positioned on the inside surface of the component receiving cavity such as disclosed in commonly assigned U.S. patent application Ser. No. 10/982,176, filed Nov. 5, 2004, the disclosure which is hereby incorporated by reference in its entirety. This type of voltage regulator includes a substrate with active and passive components mounted on the substrate and wire stand-up leads that are soldered and connected to the housing terminals or internal lead frame terminals by soldering. Other designs include resistance welding any stand-up leads to internal lead frame terminals, but with the different active and passive components and stand-up leads still soldered to a substrate.

Another approach replaces a substrate with a printed circuit board in which some printed circuit board components are soldered to a ceramic. Some components and connectors are soldered to the board and other terminals are welded.

These proposals, however, have a number of soldered connections or junctions that can fail from shock, vibration or reflow melting. Every junction in the voltage regulator is a potential problem arising from both manufacturing and component use. It is believed that other proposals have used integrated circuits and complicated tuning circuits and welded connections, but these types of designs were complicated in circuit designs and not amenable for packaging in certain voltage regulator applications such as CS130 applications.

### SUMMARY OF THE INVENTION

In accordance with one non-limiting aspect of the present invention, a voltage regulator controls voltage supplied from a generator or alternator and includes a voltage regulator body having at least one component receiving cavity. A lead frame is embedded within the voltage regulator body and forms external lead frame connectors on the voltage regulator body that are adapted to be connected to devices controlled by the voltage regulator. The lead frame also forms internal lead frame connectors within the component receiving cavity. The internal lead frame components expose connection paths to optimize the use of space in the at least one component receiving cavity. A voltage regulator integrated circuit (IC) and passive components are mounted within the component receiving cavity and each connected to selected internal lead frame connectors at a connection, such as a welded or mechanical connection, such that the voltage regulator IC and passive components form a voltage regulating circuit. Each connection is preferably formed as a welded connection, for example, a resistance welded connection. The lead frame is configured such that one or more passive components are positioned over or under at least a portion of the voltage regulator IC.

In yet another aspect, the lead frame extends into the at least one component receiving cavity and includes one of a raised or lowered portion or a combination of raised or lowered portions allowing one or more passive components to be mounted over, under or a combination of both to a portion of the voltage regulator IC. A heat sink can be connected to the voltage regulator IC in yet another aspect.

In yet another aspect, the voltage regulator IC is formed as an All Silicon Voltage Regulator (ASVR). The passive components can include a varistor operative with the voltage regulator IC. The varistor could be connected between a battery sense input terminal and the ground terminal of the voltage regulator IC. A diode could be connected between the lamp output terminal and the ground terminal of the voltage regulator IC. The voltage regulator, in one non-limiting example, is adapted for use in B-circuit (high-side) vehicle system applications.

In yet another aspect, the lead frame connectors are not necessarily configured to allow passive components to be positioned over or under or a combination of both to at least a portion of the voltage regulator IC, but typically would include at least a varistor and a diode.

A method of forming a voltage regulator is also set forth.

### BRIEF DESCRIPTION OF THE DRAWINGS

Other objects, features and advantages of the present invention will become apparent from the detailed description of the invention which follows, when considered in light of the accompanying drawings in which:

FIG. 1 is an isometric view of a voltage regulator used in CS130 and similar series alternator applications and showing basic components of the voltage regulator body and external lead frame connectors.

FIG. 2 is an exploded isometric view of a prior art voltage regulator used in some CS130 and similar series alternators and showing a substrate board and the board or component receiving cavity in which the substrate and its components are placed.

FIG. 3 is an isometric view of the prior art voltage regulator shown in FIG. 2 and showing the substrate board received within the board or component receiving cavity.

FIG. 4 is an enlarged isometric view of a portion of the prior art voltage regulator of FIG. 3 and showing the substrate board received in the board receiving cavity and conductive pins that are bent and soldered to lead frame internal terminals.

FIG. 5 is an enlarged plan view of the component receiving cavity of a prior art voltage regulator similar to that shown in FIG. 4, and showing the stand-up leads welded to the internal lead frame terminals.

FIG. 6 is an enlarged plan view of the component receiving cavity in another prior art voltage regulator and showing a substrate replaced with a printed circuit board (PCB) and the PCB components and connectors soldered to the board, but using welded connections to any internal lead frame terminals.

FIG. 7 is an enlarged isometric view of a portion of a voltage regulator and its component receiving cavity, and showing passive components and an integrated circuit mounted therein and using all welded connections, in accordance with one non-limiting example of the present invention.

FIG. 8 is a top plan view of the component receiving cavity shown in FIG. 7.

FIG. 9 is a top plan view of the voltage regulator in accordance with one non-limiting example of the present invention.

FIG. 10 is a sectional view taken along line 10-10 of FIG. 9, and showing the overall configuration of the lead frame such that one or more passive components are positioned over at least a portion of the voltage regulator integrated circuit, in accordance with one non-limiting example of the present invention.

FIG. 11 is an isometric view in partial cut-away showing the voltage regulator body, the component receiving cavity, the lead frame and active and passive components mounted within the cavity and connection to the lead frame connectors.

FIG. 12 is an enlarged isometric view of a portion of the voltage receiving cavity shown in FIG. 11 and showing in greater detail the lead frame and interconnected active and passive components.

FIG. 13 is another isometric view of the voltage regulator with some lines in phantom, such as shown in FIG. 11, but showing greater details of the lead frame configuration within the voltage regulator body.

FIG. 14 is an enlarged isometric view of a portion of the component mounting cavity shown in FIG. 13 and showing the lead frame and interconnected passive components and the voltage regulator IC.

FIG. 15 is a top plan view of the voltage regulator, in accordance with a non-limiting example of the present invention, with its cover removed and showing the passive components welded to internal lead frame connectors.

FIG. 16 is a bottom plan view reversed in direction from that shown in FIG. 15 with a heat sink removed and showing the voltage regulator IC having terminals welded to the internal lead frame connectors.

FIG. 17 is an enlarged plan view of the component mounting cavity of FIG. 15 and showing the passive components and the welded connections.

FIG. 18 is a schematic circuit diagram showing an example of the type of circuit interconnection among the voltage regulator IC and passive components in accordance with one non-limiting example of the present invention.

FIG. 19 is an isometric view of an example of a voltage regulator IC that can be used for the circuit shown in FIG. 18.

FIG. 20 is a plan view of the voltage regulator IC shown in FIG. 19 used in accordance with one non-limiting example of the present invention.

### DETAILED DESCRIPTION OF THE PREFERRED EMBODIMENTS

Different embodiments will now be described more fully hereinafter with reference to the accompanying drawings, in which preferred embodiments are shown. Many different forms can be set forth and described embodiments should not be construed as limited to the embodiments set forth herein. Rather, these embodiments are provided so that this disclosure will be thorough and complete, and will fully convey the scope to those skilled in the art. Like numbers refer to like elements throughout, and prime notation is used to indicate similar elements in alternative embodiments.

In accordance with one non-limiting example of the present invention, a voltage regulator includes both a voltage regulator integrated circuit (IC) and passive components mounted within at least one component receiving cavity of a voltage regulator body, each connected to selected internal lead frame connectors at a connection, typically formed by resistance welding or in some cases, a strong mechanical bond. The voltage regulator IC and passive components form a voltage regulating circuit. The lead frame is configured in one non-limiting aspect such that one or more passive components are positioned over or under or a combination of both to at least a portion of the voltage regulator IC. It should be understood that lead frame refers to the metallic or other material embedded within the voltage regulator body, and can be formed by one or more sections, connected or separate, and forming internal lead frame terminals in the cavity and external terminals, including terminals in a slot that receives a wiring harness.

In yet another non-limiting aspect of the present invention, the passive components include a varistor operative with the voltage regulator IC and operatively connected between the battery sense input terminal and the ground terminal of the voltage regulator IC. A diode can be operatively connected between the lamp output terminal and the ground terminal of the voltage regulator IC. The voltage regulator is typically adapted for use in B-circuit (high-side) vehicle system applications, for example, CS130 and similar alternator applications.

In another non-limiting example, the voltage regulator IC can be formed as a flip chip or other configuration and connected such as by resistance welding to the internal lead frame connectors. Passive or “discrete” components are connected, for example, resistance welded to the internal lead frame connectors. It should be understood that “discrete” components is a term that can also be synonymously used for the term “passive” components, such as a varistor, resistor and diode as explained below. This type of voltage regulator design in accordance with non-limiting examples of the present invention overcomes the disadvantages from using solder joints that can fail from shock, vibration and reflow (melting). As a result, the voltage regulator, in accordance with non-limiting examples of the present invention, has a longer component life, better cost value and a quality that meets or exceeds the original equipment specifications.

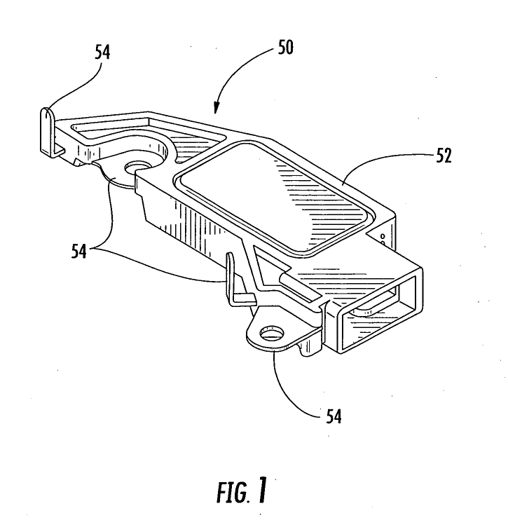

FIG. 1 is an isometric view of a standard voltage regulator 50 such as used on a B-circuit (high-side) voltage regulation system for an automobile, for example, on General Motors vehicles that use CS121, CS130, and CS144 series alternators, for example, as manufactured by Delco as non-limiting examples. This type of CS130 regulator is typically a 12 volt regulator with a 2.5 second LRC with PLFS terminals. Typical manufacturers include Delco (OE): D685; USI; 71-10028; Taditel: T437; and Transpo: D411/D411XHD.

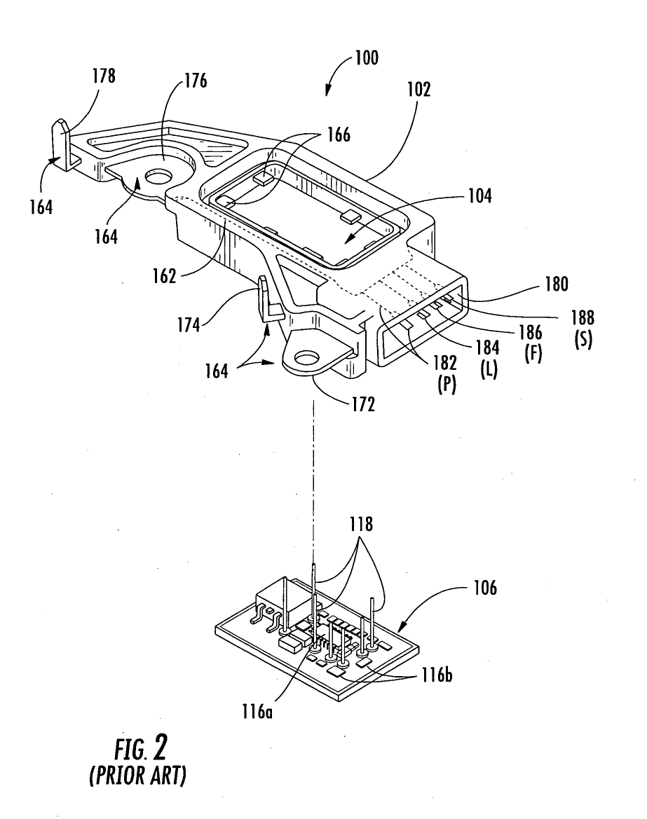

One commercial example of this type of voltage regulator is a D411 voltage regulator sold by Transpo Electronics, Inc. This type of voltage regulator 50 includes a voltage regulator body 52 having a component receiving cavity (not shown in this view), which is typically covered. A lead frame is embedded within the voltage regulator body and forms external lead frame connectors 54 on the voltage regulator body, as illustrated. Details of the different external connectors and their function and internal lead frame connectors will be described relative to an example of a prior art voltage regulator shown in FIGS. 2-4.

A prior art voltage regulator 100 such as disclosed in the copending and commonly assigned '176 application is now described relative to FIGS. 2-4. This voltage regulator includes a component receiving cavity that receives a substrate such as shown in FIG. 2. The stand-up leads as will be described are soldered to the substrate and also soldered to any internal lead frame connectors, for example, connectors shown as the small tabs 166 in FIGS. 2 and 3.

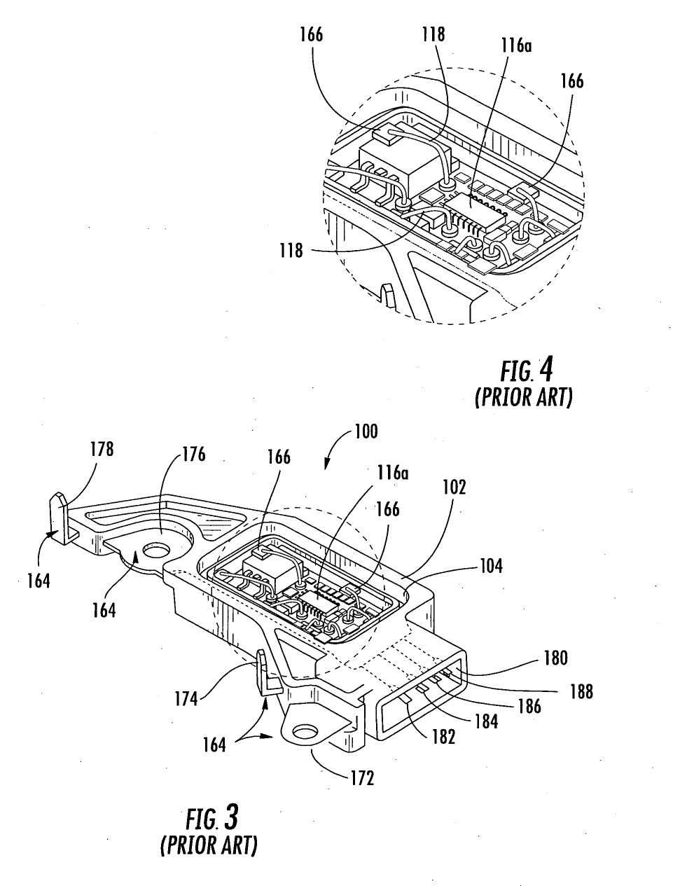

In this particular embodiment, the voltage regulator body 102 is formed from an insulator material with an embedded lead frame shown by dashed lines within the voltage regulator body. The lead frame 162 includes external lead frame terminals 164 that connect to wires and terminals of various devices controlled by the voltage regulator, or receive signals from other devices. The board or component receiving cavity 104 in this example is an open cavity as illustrated (later covered in the final product) and includes internal lead frame terminals 166 extending from the lead frame that connect to the terminal connections 118 formed as conductive pins extending from the substrate board 106, which are bent and soldered onto the internal lead frame terminals 166 as shown in FIGS. 3 and 4. The substrate board includes active components 116a, for example, an IC or transistor, and passive components 116b, for example, resistors.

FIG. 3 shows that the substrate board 106 is received into the component receiving cavity 104 from underneath. A cavity cover (not shown) can be placed over the cavity after the substrate board is inserted therein. Two opposing cavity covers could be used on one and the other side filled with insulative material. Silicon gel can be used as a fill, or even epoxy or urethane or no filling material. The different external lead frame terminals 164 include a ground connection 172, a field connection 174, a battery (B+) connection 176 that acts as a B+terminal and a stator connection 178. The lead frame assembly can receive a wiring harness connector within a wiring slot 180 and includes a sense connector 182 for B+, an ignition connector 184, a lamp connector 186 and a stator or shorted stator connector 188 as shown by the dashed lines.

During assembly, when the substrate board 106 is received into the board receiving cavity 104, all conductive pins 118 are typically bent inward so that they do not interfere with the embedded conductors forming the internal terminals 166. The silicon gel or conductive epoxy or other adhesive can be used to secure the substrate board 106 and later a cavity cover. The conductive pins are bent and soldered to the internal terminals and the component receiving cavity 104 is filled with a silicon gel. The cavity cover is then placed over the cavity and secured using epoxy.

The illustrated voltage regulator 100 is typically used with CS-series voltage regulators, for example, with a CS130 series alternator, but it should be understood that it can be used on different types of alternators. In this prior art example, the voltage regulator circuit could incorporate a field effect transistor having a drain terminal connected to B+ and to an integrated circuit chip, for example, its terminal A. An external sense connector could be connected to terminal 3 of the IC chip, which typically has dual sensing ability, either external or internal. This voltage regulator 100 is a B-circuit as a high-side drive with a voltage set point at about 14.7 volts. This voltage regulator can be light activated and the stator input can turn off the light. It preferably has a soft start feature.

Typically, in this type of voltage regulator application, the substrate board and its mounted active and passive components are covered completely with a conformal coating and cured at room temperature for about 15 minutes. It is possible to inspect with a UV inspection light and further curing can occur at 80° C. for 15 minutes. The insulator material, for example, a voltage encapsulant base with urethane activator, can act as an adhesive and fill the component receiving cavity.

This and other types of substrate board could be mounted to a ceramic, or could be formed as a separate substrate board, for example, such as disclosed in the copending and commonly assigned '176 patent application that includes a metallic base layer, insulator layer on the metallic base layer, and circuit layer typically formed from copper on the insulator layer and defining a printed circuit pattern. Active components, for example transistors, and passive components, for example capacitors and resistors, can be interconnected by a printed circuit pattern formed as a circuit layer. The metallic base layer could be formed from aluminum or copper, but also could be avoided as a base layer altogether. The substrate board as described could avoid a large heat sink and associated mounting hardware or other thermal interface material.

The substrate board is operable to minimize solder joint fatigue and enhance heat spreading, but still uses a large number of soldered joints as illustrated. Although the number of required interconnections that are soldered are reduced because of surface mount technology applications, reflow soldering techniques, and the use of automatic pick and place equipment for inserting the substrate board into the component or component receiving cavity, there is still the drawback of the soldered connections.

Another prior art voltage regulator 200 having a reduced number of soldered connections is shown in FIG. 5 in which components similar to that shown in FIGS. 2-4 are illustrated and given a 200 series of number identification, for example, the body 202, cavity 204 and components 216a, 216b. In this example, the stand-up leads 218 are resistance welded to terminals 266. The components 216a, 216b and stand-up leads are still soldered to some type of substrate as illustrated. An integrated circuit 393 includes terminals 393a resistance welded to components that are soldered to the board. In one non-limiting example, there are 34 junctions and 27 soldered junctions.

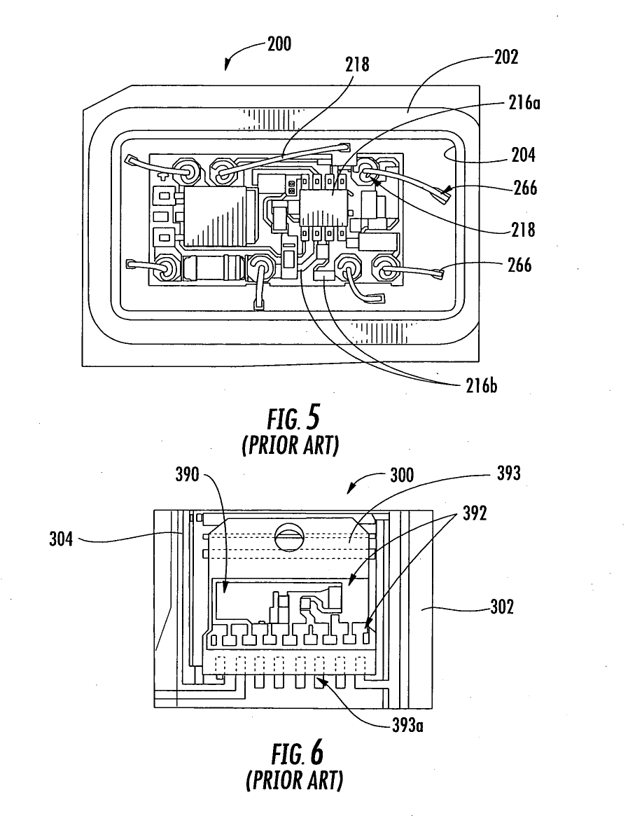

FIG. 6 is another prior art voltage regulator 300 that reduces the number of soldered connections, for example, similar to a voltage regulator manufactured by Taditel under the designation T437. Reference numerals begin in the 300 series. A substrate board is replaced with a printed circuit board (PCB) 390 and components and connectors indicated generally at 392 are soldered to a board. The PCB is shown at 390 and components and connectors are soldered to the board and include welded terminals and integrated circuit terminals. An integrated circuit 393 includes terminals 393a resistance welded to components that are soldered to the board. This embodiment includes 17 junctions and 10 soldered junctions.

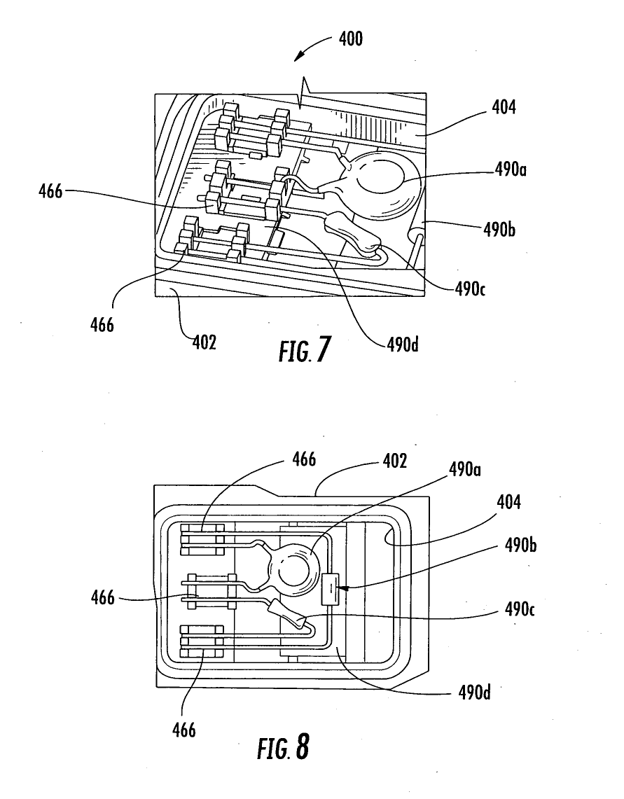

In accordance with non-limiting examples of the present invention, FIGS. 7-17 are different views of a voltage regulator 400, such as a modified D411XHD manufactured and sold by Transpo Electronics, Inc., in which a voltage regulator integrated circuit (IC) is connected, for example, welded, typically to housing terminals, referred also as internal lead frame connectors, within at least one component receiving cavity of the voltage regulator body. Passive components are connected, for example, welded to internal lead frame connectors typically by resistance welding, but other non-soldered connections, such as a tight mechanical bond, could be used. A tight crimp with connectors, such as shown in FIGS. 7, 12 and 14, could possibly be used. Functional components similar to those shown in FIGS. 2-4 are given reference numerals in the 400 series, such as the components 480, 482, 484, 486, 488 corresponding to components 180, 182, 184, 186, 188 described relative to FIG. 2. Although one component receiving cavity is illustrated, more than one cavity could be used.

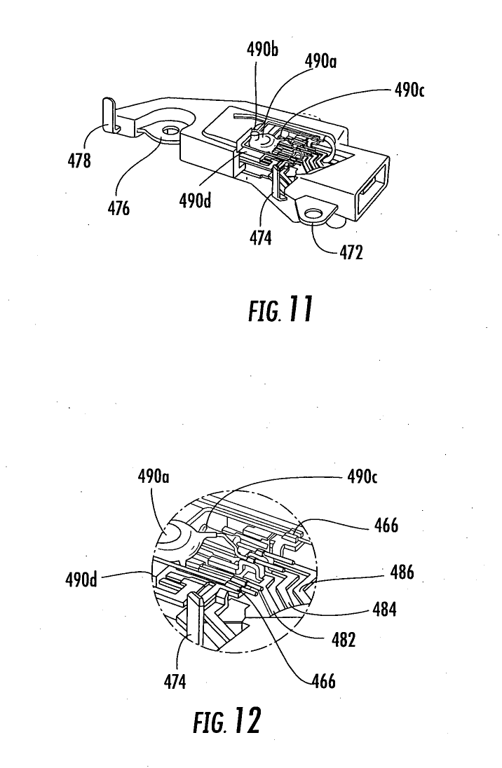

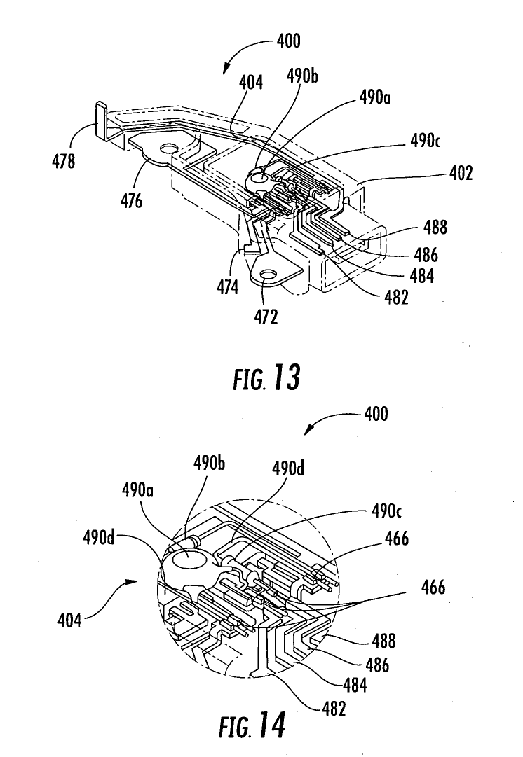

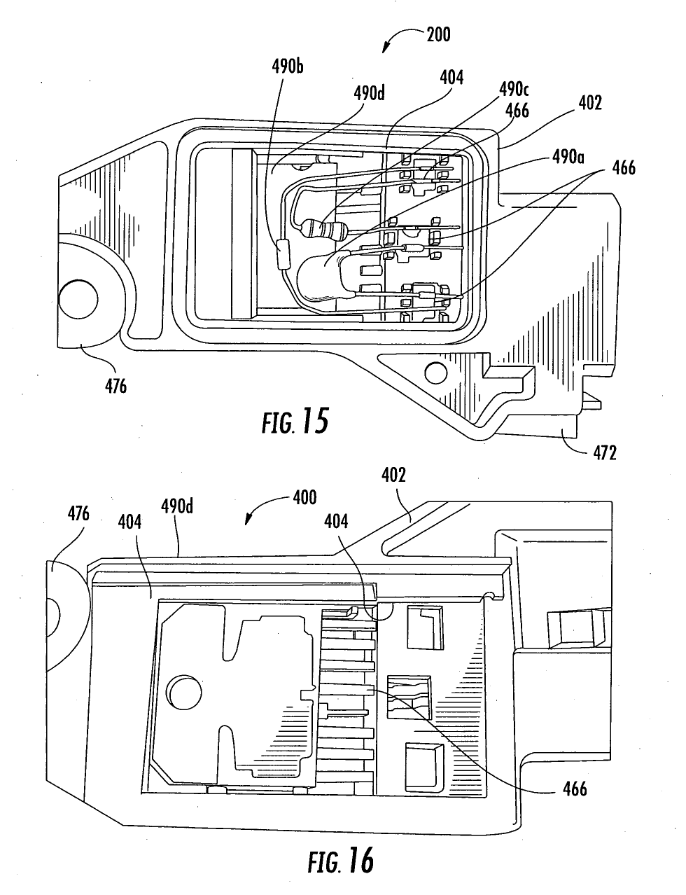

FIGS. 7 and 8 show how three passive components, in this example a varistor 490a, diode 490b and resistor 490c, are positioned relative to the voltage regulator integrated circuit 490d (FIG. 10), such that one or more passive components are positioned over at least a portion of the voltage regulator IC 490d. It should be understood that the lead frame can be formed such that the internal lead frame components expose connection paths to optimize the use of space in the at least one component receiving cavity. The lead frame 462 extending into the component receiving cavity 404 includes a raised portion 462a (FIG. 10) defining terminals allowing one or more of the passive components 490a, 490b, 490c to be mounted over at least a portion of the voltage regulator IC 490d as better shown in FIG. 10 and in the cut-away views of FIGS. 11 and 13 and the enlarged view shown in FIGS. 12 and 14. Although a raised portion is illustrated, a lowered portion or combination of a raised portion and lowered portion could be used, allowing components to be positioned over, under or a combination of both to a portion of the IC. If space is optimized, they could be formed to the side. As shown in FIG. 10, a heat sink 491 can be connected to the voltage regulator IC 490d. Of course, the lead frame 462 is embedded within the voltage regulator body and can be formed as separate sections that are connected and not connected to form various lead frame connectors and external lead frame connectors.

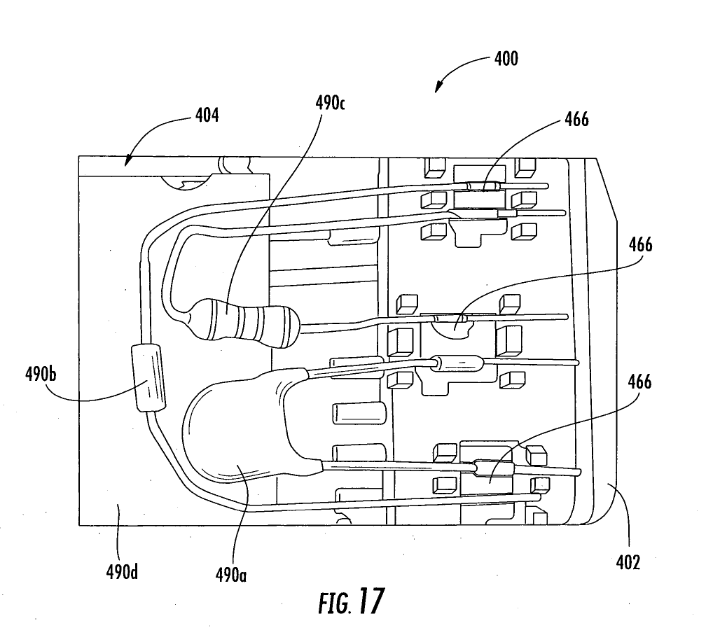

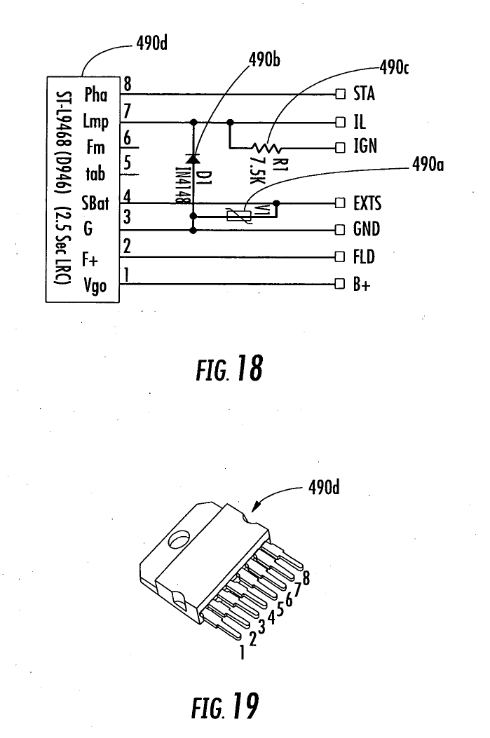

FIGS. 15 and 17 are plan views looking into the component receiving cavity 404 and showing the welded connection between the passive components 490a, 490b, 490c and the internal lead frame connectors 466. FIG. 16 is a plan view reversed in direction from FIGS. 15 and 17 and showing the voltage regulator IC 490d having its terminals welded to the lead frame connectors 466 within the component receiving cavity 404. In FIG. 16, the heat sink 491 as shown in FIG. 10 has been removed. The lead frame connectors 466 are not tabs as illustrated in FIGS. 2-4, but are configured to include terminal sections for possible wire bonding of passive component leads and IC terminals or similar connections as illustrated in FIGS. 12 and 14. The lead frame connectors are designed to connect to appropriate voltage regulator IC terminals and passive components for proper circuit connection to the external terminals.

Although resistance welding is typically used as shown in the examples from FIGS. 15-17, other welding processes can be used. Heat can be obtained from the resistance of work pieces to the flow of welding current in the circuit. The amount of amperage can vary. An example of such welding could be spot welding to join overlapping portions of metals. Different types of machines can be used, including resistance spot welding machines such as a horn or rocker arm type and a pressed type. Multiple spot welding machines could be used or other resistance welding machines.

The different terminals of the voltage regulator IC 490d and the passive components such as the varistor 490a, diode 490b and resistor 490c can be connected to the various internal lead frame connectors by wire bonding such as more particularly shown in FIGS. 7, 8, 12 and 14 in which the wire leads of the passive components are received in the various internal lead frame connectors and resistance welded.

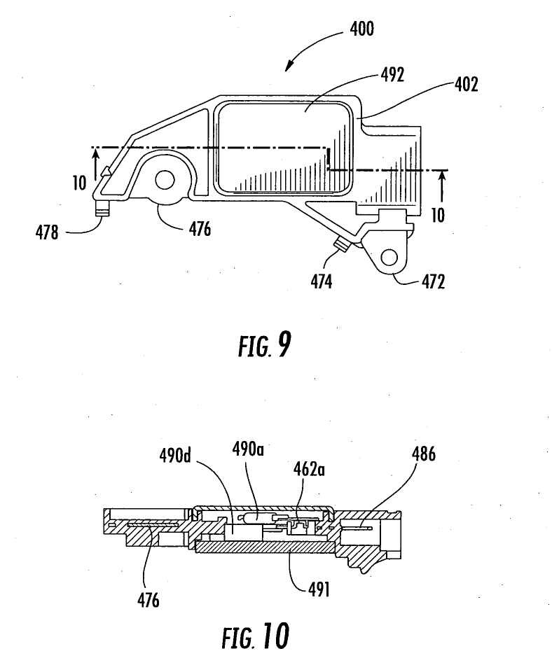

After resistance welding, a cover 492 (FIG. 9) can be placed on the voltage regulator over the component receiving cavity after it has been filled with a dielectric as explained before. The heat sink 491 could be used as a metallic surface for engaging various ground surfaces as known to those skilled in the art.

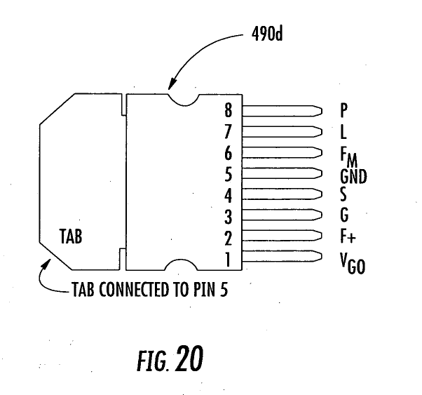

FIGS. 19 and 20 are examples of a voltage regulator IC 490d, which in one non-limiting example, could be an all silicon voltage regulator (ASVR) sold under the designation L9468 by STMicroelectronics. This type of ASVR is a multi-watt package formed as a monolithic multi-function generator voltage regulator that can regulate the output of an automotive generator by controlling field winding current using a variable frequency PWM high side driver. A pin description is indicated below corresponding to the pins shown in FIGS. 19 and 20. Further description of the L9468 can be found in a technical data sheet entitled, L9468 “All Silicon Voltage Regulator,” published in April 2005 by STMicroelectronics. The pin description is as follows:

| No | Pin | Function |
|---|---|---|
| 1 | V_{GO} | Generator output sense and voltage |
| | | supply |
| 2 | F+ | Field high side driver output |
| 3 | G | Ground |
| 4 | S | Battery sense input |
| 5 | GND | Connected to the tab through the |
| | | frame |
| 6 | F_{M} | Field monitor output |
| 7 | L | Lamp terminal low side driver |
| 8 | P | Phase sense input |

FIG. 18 is a schematic circuit diagram showing how the three passive components as the varistor 490a, diode 490b and resistor 490c are connected to the voltage regulator IC 490d. The varistor 490a is connected between the battery sense terminal and ground and the diode 490b is connected between the lamp terminal and low side driver and ground. The right side of the schematic circuit diagram shows various connections to other automobile components. As shown in FIG. 20, the tab can act as a ground and is connected to pin 5 as ground.

In the specific configuration shown in FIG. 18 for the exemplary schematic circuit diagram, the lead frame is configured as shown in detail in FIGS. 10-14 such that the lead frame 462 includes a raised portion 462a and is bent upward to permit at least one or more passive components such as the varistor 490a to be positioned or mounted over at least a portion of the voltage regulator IC 490d. This allows a tight packaging of the voltage regulator IC and passive components to fit into the voltage regulator body as shown in FIG. 1 and the other figures. Other lead frame configurations could be used, such as bent downward, horizontal, or configured or bent in other directions.

The varistor 490a could be a surge protection device that could be connected across an AC input, for example, the ground and the internal sense connector for the battery. As typical with varistors, it can create a shunt path. The varistor 490a could be formed as a metal oxide varistor and have significant non-ohmic current-voltage characteristics. The varistor 490a could contain a mass of zinc oxide grains in a matrix of other metal oxides, sandwiched between two metal plates as electrodes. The boundary between each grain and its neighbor could form a diode junction to allow current to flow in one direction. The randomly oriented grains could be electrically equivalent to a network of back-to-back diode pairs in parallel with many other pairs.

An example of a diode 490b could be a 100 volt switching diode and the resistor 490c could be a 0.25 watt, 7.5K ohm, 5% resistor in these non-limiting examples. The use of these three passive components and the voltage regulator IC is a improved and simplified circuit design for this type of voltage regulator and allows efficient and compact packaging.

It should be understood that the voltage regulator 400 as described is illustrated as a voltage regulator for use in B-circuit (high-side) vehicle system applications. The particular resistance welded connections, the circuit configuration, and the bent lead frame as described could be used in other voltage regulators, including those adapted for use in marine engine applications, motorcycle applications, A-circuit (low-side) vehicle applications, and permanent magnet applications as non-limiting examples. It could also be used in a Mercury-Marine engine application in which a regulator body could be formed as a metallic housing or “can” as referred to by those skilled in the art.

An example A-circuit (low-side) voltage regulator could be Mitsubishi voltage regulators, for example, used on Ford Tracer, Probe and Mazda and similar vehicles. Another example is a voltage regulator sold under the designation IM265 by Transpo Electronics, Inc., and has a system voltage of 12 volts as used on the “A” circuit or low-side drive with a trio excitation. It could be indicator light activated, and in one example, could use a 28 millimeter brush ring and have an operating temperature range of about −40° C. to about 125° C. It could have a field current of about 4 amps and a voltage set point at 4000 RPM of about 14.5 volts. It typically would include a B-terminal and a field terminal at the top. The voltage regulator could also be used such as for Harley-Davidson motorcycles sold under the designation H1988 by Transpo Electronics, Inc. Many other non-limiting examples are possible.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A voltage regulator for controlling voltage supplied from a generator or alternator comprising:
a voltage regulator body having at least one component receiving cavity;
a lead frame embedded within the voltage regulator body, said lead frame forming external lead frame connectors on the voltage regulator body that are adapted to be connected to devices controlled by the voltage regulator and forming internal lead frame connectors within the at least one component receiving cavity wherein the internal lead frame connectors expose connection paths to optimize the use of space in the at least one component receiving cavity; and
a voltage regulator integrated circuit (IC) and passive components mounted within the at least one component receiving cavity and each connected to selected internal lead frame connectors at a connection such that said voltage regulator IC and passive components form a voltage regulating circuit, wherein the lead frame is configured such that one or more passive components are positioned over or under or a combination of both to at least a portion of the voltage regulator IC.

2. A voltage regulator according to claim 1 wherein said lead frame extending into the at least one component receiving cavity includes a raised portion or lowered portion or a combination of both allowing one or more passive components to be mounted over, under or a combination of both to at least a portion of the voltage regulator IC.

3. A voltage regulator according to claim 1 and further comprising a heat sink connected to said voltage regulator IC.

4. A voltage regulator according to claim 1 wherein said voltage regulator IC comprises an all silicon voltage regulator (ASVR).

5. A voltage regulator according to claim 1 wherein said passive components comprise a varistor operative with said voltage regulator IC.

6. A voltage regulator according to claim 5 wherein said voltage regulator IC includes a battery sense input to which said varistor is operatively connected.

7. A voltage regulator according to claim 5 wherein said passive components further comprise a diode operatively connected to a lamp output terminal of the voltage regulator IC.

8. A voltage regulator according to claim 1 wherein said voltage regulator is adapted for use in B-circuit (high-side) vehicle system applications.

9. A voltage regulator according to claim 1 wherein each connection comprises a welded or mechanical connection.

10. A voltage regulator for controlling voltage supplied from a generator or alternator comprising:
a voltage regulator body having at least one component receiving cavity;
a lead frame embedded within the voltage regulator body, said lead frame forming external lead frame connectors on the voltage regulator body that are adapted to be connected to devices controlled by the voltage regulator and forming internal lead frame connectors within at least one the component receiving cavity wherein the internal lead frame connectors expose connection paths to optimize the use of space in the at least one component receiving cavity; and
a voltage regulator integrated circuit (IC) and passive components mounted within the at least one component receiving cavity and each connected to selected internal lead frame connectors at a connection such that said voltage regulator IC and passive components form a voltage regulating circuit, said passive components including a varistor operatively connected to said voltage regulator IC.

11. A voltage regulator according to claim 10 wherein said lead frame extending into the at least one component receiving cavity includes a raised portion or lowered portion or a combination of both allowing one or more passive components to be mounted over, under or a combination of both to at least a portion of the voltage regulator IC.

12. A voltage regulator according to claim 10 wherein said voltage regulator IC includes a battery sense input to which said varistor is operatively connected.

13. A voltage regulator according to claim 10 wherein said passive components further comprise a diode operatively connected to a lamp output terminal.

14. A voltage regulator according to claim 10 and further comprising a heat sink connected to said voltage regulator IC.

15. A voltage regulator according to claim 10 wherein said voltage regulator IC comprises an all silicon voltage regulator (ASVR).

16. A voltage regulator according to claim 10 wherein said voltage regulator is adapted for use in B-circuit (high-side) vehicle system applications.

17. A voltage regulator according to claim 10 wherein each connection comprises a welded or mechanical connection.

18. A method of forming a voltage regulator, which comprises:
forming a voltage regulator body having at least one component receiving cavity and a lead frame embedded within the voltage regulator body and forming external lead frame connectors that are adapted to be connected to devices controlled by the voltage regulator and extending into the component receiving cavity and forming internal lead frame connectors therein such that internal lead frame connectors expose connection paths to optimize the use of space in the at least one component receiving cavity; and
connecting a voltage regulator integrated circuit IC and passive components including a varistor to the internal lead frame connectors.

19. A method according to claim 18 which further comprises mounting the passive components such that at least one of the passive components extend over or under or a combination of both to at least a portion of the voltage regulator IC.

20. A method according to claim 18 which further comprises connecting a diode as a passive component and operatively connected to a lamp output terminal.

21. A method of forming a voltage regulator, which comprises:
forming a voltage regulator body having at least one component receiving cavity and a lead frame embedded within the voltage regulator body and forming external lead frame connectors that are adapted to be connected to devices controlled by the voltage regulator and extending into the at least one component receiving cavity and forming internal lead frame connectors therein such that internal lead frame connectors expose connection paths to optimize the use of space in the at least one component receiving cavity; and
connecting a voltage regulator integrated circuit IC and passive components to the internal lead frame connectors and configuring the lead frame such that one or more passive components are positioned over or under or a combination of both to at least a portion of the voltage regulator IC.
